(19) United States
(12) Patent Application Publication
(10) Pub. No.: US 2017/0107426 A1
(43) Pub. Date: Apr. 20, 2017

(54) EUROPIUM- OR SAMARIUM-DOPED TERBIUM MOLYBDATES

(71) Applicant: MERCK PATENT GMBH, Darmstadt (DE)

(72) Inventors: Ralf PETRY, Griesheim (DE); Thomas JUESTEL, Witten (DE); Florian BAUR, Muenster (DE)

(73) Assignee: MERCK PATENT GMBH, Darmstadt (DE)

(21) Appl. No.: 15/127,247

(22) PCT Filed: Feb. 17, 2015
(86) PCT No.: PCT/EP2015/000345

§ 371 Date: Sep. 19, 2016

(30) Foreign Application Priority Data
Mar. 18, 2014 (DE) 10 2014 003 848.3

(51) Int. Cl. C09K 11/77; H05B 33/18; H01L 33/50

(52) U.S. Cl. CPC C09K 11/7794; C09K 11/7776; H01L 33/502; H05B 33/18

(57) ABSTRACT

The invention relates to europium or samarium-doped terbium molybdates, to a method for producing said compounds, and to the use of the claimed europium or samarium-doped terbium molybdates as conversion lumiophores. The invention also relates to a light-emitting device containing a claimed europium or samarium-doped terbium molybdate.

The present invention relates to europium- or samarium-doped terbium molybdates, to a process for the preparation of these compounds, and to the use of the europium- or samarium-doped terbium molybdates according to the invention as conversion phosphors. The present invention furthermore relates to a light-emitting device which comprises a europium- or samarium-doped terbium molybdate according to the invention.

Inorganic fluorescent powders which can be excited in the blue and/or UV spectral region are of major importance as conversion phosphors for phosphor-converted LEDs, pc-LEDs for short. In the meantime, many conversion phosphor systems are known, such as, for example, alkaline-earth metal orthosilicates, thiogallates, garnets, nitrides and oxynitrides, each of which are doped with Ce³⁺ or Eu²⁺. Besides the yellow- or green-emitting garnets or orthosilicates, the achievement of warm-white light sources having colour temperatures <4000 K based on blue- or UV-A-emitting (In,Ga)N LEDs requires red-emitting phosphors having emission wavelengths above 600 nm which emit sufficiently strongly at the corresponding wavelength of the primary radiation (370-480 nm). At the same time, the stability of these phosphors must be similarly high as that of the garnets or orthosilicates in order that an undesired colour point shift does not occur during the lifetime of the solid-state light source.

A number of phosphors which meet these requirements have been proposed or developed for this purpose in the last 20 years. The phosphors used to date, namely (Ca,Sr)S:Eu, (Ca,Sr)AlSiN₃:Eu and (Ca,Sr,Ba)₂Si₅N₈:Eu, are all based on the activator Eu²⁺, which is distinguished both by a broad absorption spectrum and also by a broad emission band. The main disadvantage of these Eu²⁺-activated materials is their relatively high sensitivity with respect to photodegradation, since the divalent Eu²⁺ tends towards photoionisation, in particular in host materials having a relatively small band gap.

A further disadvantage is the fairly high half-value width of the Eu²⁺ emission band, which is evident from a moderate lumen equivalent (<200 lm/W) if the colour point is in the deep-red spectral region. This observation applies, in particular, to the phosphors (Ca,Sr)S:Eu and (Ca,Sr)AlSiN₃:Eu.

It is therefore desirable to develop a red-emitting phosphor which does not have these disadvantages. One of the objects of the present invention is thus to provide phosphors of this type.

Surprisingly, the inventors have found that europium- or samarium-doped terbium molybdates meet the above-mentioned requirements.

CN 103275713 A discloses in this connection compounds of the general formula

R^{III}₂₍₁₋ₓ₎EU₂ₓMo₄O₁₅

in which R^{III} is selected from the elements La³⁺, Ce³⁺, Pr³⁺, Nd³⁺, Sm³⁺, Gd³⁺, Tb³⁺, Dy³⁺, Ho³⁺, Er³⁺, Tm³⁺, Yb³⁺, Lu³⁺, Sc³⁺ and Y³⁺ and 0.0001≦x<1.0. However, the terbium molybdates according to the invention are not disclosed here. As is additionally known to the person skilled in the art, Tb⁴⁺ additionally forms alongside Tb³⁺ in the preparation of compounds of the above-mentioned formula, which significantly impairs the phosphor properties of the corresponding compounds, since corresponding Tb⁴⁺ fractions in the compounds cause a broad absorption band, which disadvantageously extends into the region of red light.

The present invention therefore relates to a compound of the formula I,

(Tb₂)ₓ(Mo_{1-b}W_{b})_{y}O_{3x+3y}:Ln I

in which
Ln denotes Sm³⁺ or Eu³⁺;
x denotes 1, 2 or 3; 1≦y≦8; and 0≦b<1.
y preferably corresponds to an integer multiple of 1 to 8.

The compounds according to the invention can usually be excited in the blue spectral region, preferably at about 370-480 nm, and usually have red line emission in the red spectral region at about 615 or 660 nm.

In the context of this application, blue light denotes light whose emission maximum is between 400 and 459 nm, cyan light denotes light whose emission maximum is between 460 and 505 nm, green light denotes light whose emission maximum is between 506 and 545 nm, yellow light denotes light whose emission maximum is between 546 and 565 nm, orange light denotes light whose emission maximum is between 566 and 600 nm and red light denotes light whose emission maximum is between 601 and 700 nm. The compound according to the invention is preferably a red-emitting conversion phosphor.

Furthermore, the compounds according to the invention are distinguished by a high photoluminescence quantum yield of greater than 80%, preferably greater than 90%, particularly preferably greater than 95%.

The photoluminescence quantum yield (also called quantum yield or quantum efficiency) describes the ratio between the number of photons emitted and absorbed by a compound.

In addition, the phosphors according to the invention have high values for the lumen equivalent (≧250 lm/W) and are furthermore distinguished by high chemical and photochemical stability.

In a preferred embodiment, the compounds of the formula I are selected from the formula Ia,

(Tb₂₋ₐLnₐ)ₓ(Mo_{1-b}W_{b})_{y}O_{3x+3y} Ia

in which
Ln and b have one of the meanings indicated under formula I,
x=1;
1≦y≦3; and
0.1≦a≦1.

The compounds according to the invention are distinguished, in particular, by an absorption strength at 395 nm, 465 nm and 487 nm which is comparatively high for Ln-doped phosphors. The last-mentioned absorption band is due to the presence of trivalent Tb³⁺ (⁷F₆-⁵D₄), with the “green” Tb³⁺ luminescence being quenched virtually completely by efficient energy transfer to Ln at a concentration 0.2≦a≦1.

In a preferred embodiment of the present invention, Ln is equal to Eu³⁺. Preference is therefore given to compounds of the formula I or Ia in which 0.1<a≦1, particularly preferably in which 0.2≦a≦1, in particular in which 0.4<a≦1.

In a further preferred embodiment, Ln in the compounds of the formulae I and Ia according to the invention is equal to Sm³⁺, preferably where 0.1≦a≦1, particularly preferably in which 0.2<a≦1, furthermore 0.4≦a≦1.

In accordance with the invention, the emission maximum of the compounds of the formulae I and Ia where Ln is equal to Eu³⁺ or Sm³⁺ can also if necessary be shifted into the yellow spectral region by doping in less Ln, particular preference being given here to compounds in which 0<a<0.1, preferably 0<a≦0.05, particularly preferably 0<a≦0.01.

In a further embodiment, the hexavalent molybdenum in the compounds of the formulae I and Ia can be partially replaced by hexavalent tungsten (b>0). Preference is given here to compounds in which 0≦b<0.8, particularly preferably in which 0≦b<0.5, in particular in which 0≦b<0.3. However, especial preference is given to compounds of the formulae I and Ia in which b is equal to 0.

Particular preference is given to compounds of the formulae I and Ia in which x is equal to 1 and y is simultaneously equal to 3, furthermore compounds of the formulae I and Ia in which x is equal to 2 and y is simultaneously equal to 7, and compounds of the formulae I and Ia in which x is equal to 3 and y is simultaneously equal to 8.

In particular, the compounds of the following sub-formula (Tb₁₋ₐEuₐ)₂Mo₃O₁₂ according to the invention are distinguished by the existence of a gap-free mixed-crystal series.

Mixed crystal denotes a crystal which consists of at least two different chemical elements, where the corresponding atoms or ions are randomly distributed.

The compounds according to the invention are particularly preferably selected from the following sub-formulae:

Tb_{1.6}Eu_{0.4}Mo₃O₁₂, Tb_{1.4}Eu_{0.6}Mo₃O₁₂, Tb_{1.2}Eu_{0.8}Mo₃O₁₂, Tb_{1.0}Eu_{1.0}Mo₃O₁₂, and Tb_{1.8}Sm_{0.2}Mo₃O₁₂, Tb_{1.6}Sm_{0.4}Mo₃O₁₂, Tb_{1.4}Sm_{0.6}Mo₃O₁₂, Tb_{1.2}Sm_{0.8}Mo₃O₁₂ and Tb_{1.0}Sm_{1.0}Mo₃O₁₂.

The compounds of the formulae I and Ia are preferably in phase-pure form here.

The phase purity of a crystalline powder can be investigated by means of an X-ray diffraction pattern, i.e. whether the sample consists only of one crystalline compound (phase-pure) or a plurality of compounds (multi-phase). In phase-pure powders, all reflections can be observed and assigned to the compound.

The present invention furthermore relates to a process for the preparation of a compound according to the invention, characterised in that, in a step a), suitable starting materials selected from nitrides and oxides or corresponding reactive forms are mixed, and, in a step b), the mixture is thermally treated.

The process is preferably characterised by the following process steps:

(a) preparation of a mixture comprising a europium or samarium source, a molybdenum source and a terbium source, and also optionally a tungsten source;
(b) calcination of the mixture under oxidising conditions.

The europium or samarium source employed in step (a) can be any conceivable europium or samarium compound with which a europium- or samarium-doped terbium molybdate can be prepared. The europium or samarium source employed is preferably oxides or nitrides of the elements, in particular europium oxide (in particular Eu₂O₃) and/or europium nitride (EuN) and also, in particular, samarium oxide (in particular Sm₂O₃) and/or samarium nitride (SmN), in particular Eu₂O₃ or Sm₂O₃.

The terbium source employed in step (a) can be any conceivable terbium compound with which a europium-doped terbium molybdate can be prepared. The terbium source employed in the process according to the invention is preferably terbium nitride and/or terbium oxide.

The molybdenum and/or tungsten source employed in step (a) can be any conceivable molybdenum and/or tungsten compound with which a terbium molybdate according to the invention can be prepared. The molybdenum and/or tungsten source employed in the process according to the invention is preferably corresponding nitrides and/or oxides.

The compounds are preferably employed in a ratio to one another such that the number of atoms of the corresponding elements Ln, molybdenum and/or tungsten, and terbium essentially corresponds to the desired ratio in the product of the above-mentioned formulae. In particular, a stoichiometric ratio is used here.

The starting compounds in step (a) are preferably employed in powder form and processed with one another, for example by means of a mortar, to give a homogeneous mixture. For this purpose, the starting compounds can preferably be suspended in an inert organic solvent known to the person skilled in the art, for example acetone. In this case, the mixture is dried before calcination.

The calcination in step (b) is carried out under oxidising conditions. Oxidising conditions are taken to mean any conceivable oxidising atmospheres, such as, for example, air or other oxygen-containing atmospheres.

The calcination is preferably carried out at a temperature in the range from 700° C. to 1200° C., particularly preferably 800° C. to 1000° C. and in particular 850° C. to 950° C. The calcination duration here is preferably 2 to 14 h, more preferably 4 to 12 h and in particular 6 to 10 h.

The calcination is preferably carried out by introducing the mixtures obtained into a high-temperature oven, for example in a boron nitride vessel. The high-temperature oven is, for example, a tubular oven which contains a molybdenum foil tray.

After the calcination, the compounds obtained are optionally homogenised, where a corresponding grinding process can be carried out wet in a suitable solvent, for example in isopropanol, or dry.

In a further embodiment, the compounds according to the invention can be coated. Suitable for this purpose are all coating methods as are known to the person skilled in the art in accordance with the prior art and are used for phosphors. Suitable materials for the coating are, in particular, metal oxides and metal nitrides, in particular alkaline-earth metal oxides, such as Al₂O₃, and alkaline-earth metal nitrides, such as AlN, as well as SiO₂. The coating here can be carried out, for example, by fluidised-bed methods. Further suitable coating methods are known from JP 04-304290, WO 91/10715, WO 99/27033, US 2007/0298250, WO 2009/065480 and WO 2010/075908. It is also possible to apply an organic coating as an alternative and/or in addition to the above-mentioned inorganic coating. The coating can have an advantageous effect on the stability of the compounds and the dispersibility.

The present invention furthermore relates to the use of the compound according to the invention as phosphor, in particular as conversion phosphor.

The term “conversion phosphor” in the sense of the present application is taken to mean a material which absorbs radiation in a certain wavelength region of the electromagnetic spectrum, preferably in the blue or UV spectral region, and emits visible light in another wavelength region of the electromagnetic spectrum, preferably in the red or orange spectral region, in particular in the red spectral region. The term “radiation-induced emission efficiency” should also be understood in this connection, i.e. the conversion phosphor absorbs radiation in a certain wavelength region and emits radiation with a certain efficiency in another wavelength region. The term “shift of the emission wavelength” is taken to mean that a conversion phosphor emits light at a different wavelength, i.e. shifted to a shorter or longer wavelength, compared with another or similar conversion phosphor. The emission maximum is thus shifted.

The present invention furthermore relates to an emission-converting material comprising one or more compounds of one of the above-mentioned formulae according to the invention. The emission-converting material may consist of one of the compounds according to the invention and would in this case be equivalent to the term “conversion phosphor” defined above.

It is also possible for the emission-converting material according to the invention to comprise further conversion phosphors besides the compound according to the invention. In this case, the emission-converting material according to the invention comprises a mixture of at least two conversion phosphors, where one of these is a compound according to the invention. It is particularly preferred for the at least two conversion phosphors to be phosphors which emit light of different wavelengths which are complementary to one another. Since the compound according to the invention is a red-emitting phosphor, this is preferably employed in combination with a green- or yellow-emitting phosphor or also with a cyan- or blue-emitting phosphor. Alternatively, the red-emitting conversion phosphor according to the invention can also be employed in combination with (a) blue- and green-emitting conversion phosphor(s). Alternatively, the red-emitting conversion phosphor according to the invention can also be employed in combination with (a) green-emitting conversion phosphor(s). It may thus be preferred for the conversion phosphor according to the invention to be employed in the emission-converting material according to the invention in combination with one or more further conversion phosphors, which then together preferably emit white light.

In general, any possible conversion phosphor can be employed as a further conversion phosphor which can be employed together with the compound according to the invention. The following, for example, are suitable here: Ba₂SiO₄:Eu²⁺, BaSi₂O₅:Pb²⁺, BaₓSr₁₋ₓF₂:Eu²⁺, BaSrMgSi₂O₇:Eu²⁺, BaTiP₂O₇, (Ba,Ti)₂P₂O₇:Ti, Ba₃WO₆:U, BaY₂F₈:Er³⁺,Yb⁺, Be₂SiO₄:Mn²⁺, Bi₄Ge₃O₁₂, CaAl₂O₄:Ce³⁺, CaLa₄O₇:Ce³⁺, CaAl₂O₄:Eu²⁺, CaAl₂O₄:Mn²⁺, CaAl₄O₇:Pb²⁺, Mn²⁺, CaAl₂O₄:Tb³⁺, Ca₃Al₂Si₃O₁₂:Ce³⁺, Ca₃Al₂Si₃Oi₂:Ce³⁺, Ca₃Al₂Si₃O₂:Eu²⁺, Ca₂B₅O₉Br:Eu²⁺, Ca₂B₅O₉Cl:Eu²⁺, Ca₂B₅O₉Cl:Pb²⁺, CaB₂O₄:Mn²⁺, Ca₂B₂O₅:Mn²⁺, CaB₂O₄:Pb²⁺, CaB₂P₂O₉:Eu²⁺, Ca₅B₂SiO₁₀:Eu³⁺, Ca_{0.5}Ba_{0.5}Al₁₂O₁₉:Ce³⁺,Mn²⁺, Ca₂Ba₃(PO₄)₃Cl:Eu²⁺, CaBr₂:Eu²⁺ in SiO₂, CaCl₂:Eu²⁺ in SiO₂, CaCl₂:Eu²⁺,Mn²⁺ in SiO₂, CaF₂:Ce³⁺, CaF₂:Ce³⁺,Mn²⁺, CaF₂:Ce³⁺,Tb³⁺, CaF₂:Eu²⁺, CaF₂:Mn²⁺, CaF₂:U, CaGa₂O₄:Mn²⁺, CaGa₄O₇:Mn²⁺, CaGa₂S₄:Ce³⁺, CaGa₂S₄:Eu²⁺, CaGa₂S₄:Mn²⁺, CaGa₂S₄:Pb²⁺, CaGeO₃:Mn²⁺, CaI₂:Eu²⁺ in SiO₂, CaI₂:Eu²⁺,Mn²⁺ in SiO₂, CaLaBO₄:Eu³⁺, CaLaB₃O₇:Ce³⁺,Mn²⁺, Ca₂La₂BO_{6.5}:Pb²⁺, Ca₂MgSi₂O₇, Ca₂MgSi₂O₇:Ce³⁺, CaMgSi₂O₆:Eu²⁺, Ca₃MgSi₂O₈:Eu²⁺, Ca₂MgSi₂O₇:Eu²⁺, CaMgSi₂O₆:Eu²⁺,Mn²⁺, Ca₂MgSi₂O₇:Eu²⁺,Mn²⁺, CaMoO₄, CaMoO₄:Eu³⁺, CaO:Bi³⁺, CaO:Cd²⁺, CaO:Cu⁺, CaO:Eu³⁺, CaO:Eu³⁺, Na⁺, CaO:Mn²⁺, CaO:Pb²⁺, CaO:Sb³⁺, CaO:Sm³⁺, CaO:Tb³⁺, CaO:Tl, CaO:Zn²⁺, Ca₂P₂O₇:Ce³⁺, α-Ca₃(PO₄)₂:Ce³⁺, β-Ca₃(PO₄)₂:Ce³⁺, Ca₅(PO₄)₃Cl:Eu²⁺, Ca₅(PO₄)₃Cl:Mn²⁺, Ca₅(PO₄)₃Cl:Sb³⁺, Ca₅(PO₄)₃Cl:Sn²⁺, β-Ca₃(PO₄)₂:Eu²⁺, Mn²⁺, Ca₅(PO₄)₃F:Mn²⁺, Caₛ(PO₄)₃F:Sb³⁺, Caₛ(PO₄)₃F:Sn²⁺, α-Ca₃(PO₄)₂:Eu²⁺, β-Ca₃(PO₄)₂:Eu²⁺, α-Ca₂(PO₄)₂:Eu²⁺, Ca₂P₂O₇:Eu²⁺,Mn²⁺, CaP₂O₆:Mn²⁺, α-Ca₃(PO₄)₂:Pb²⁺, α-Ca₃(PO₄)₂:Sn²⁺, β-Ca₃(PO₄)₂:Sn²⁺, β-Ca₂P₂O₇:Sn,Mn, α-Ca₃(PO₄)₂:Tr, CaS:Bi³⁺, CaS:Bi³⁺,Na, CaS:Ce³⁺, CaS:Eu²⁺, CaS:Cu⁺,Na⁺, CaS:La³⁺, CaS:Mn²⁺, CaSO₄:Bi, CaSO₄:Ce³⁺, CaSO₄:Ce³⁺, Mn²⁺, CaSO₄:Eu²⁺, CaSO₄:Eu²⁺,Mn²⁺, CaSO₄:Pb²⁺, CaS:Pb²⁺, CaS:Pb²⁺,Cl, CaS:Pb²⁺,Mn²⁺, CaS:Pr³⁺,Pb²⁺,Cl, CaS:Sb³⁺, CaS:Sb³⁺, Na, CaS:Sm³⁺, CaS:Sn²⁺, CaS:Sn²⁺,F, CaS:Tb³⁺, CaS:Tb³⁺,Cl, CaS:Y³⁺, CaS:Yb²⁺, CaS:Yb²⁺,Cl, CaSiO₃:Ce³⁺, Ca₃SiO₄Cl₂:Eu²⁺, Ca₃SiO₄Cl₂Pb²⁺, CaSiO₃:Eu²⁺, CaSiO₃:Mn²⁺,Pb, CaSiO₃:Pb²⁺, CaSiO₃:Pb²⁺,Mn²⁺, CaSiO₃:Ti⁴⁺, CaSr₂(PO₄)₂:Bi³⁺, β-(Ca,Sr)₃(PO₄)₂:Sn²⁺Mn²⁺, CaTi_{0.9}Al_{0.1}O₃:Bi³⁺, CaTiO₃:Eu³⁺, CaTiO₃:Pr³⁺, Ca₅(VO₄)₃Cl, CaWO₄, CaWO₄:Pb²⁺, CaWO₄:W, Ca₃WO₆:U, CaYAlO₄:Eu³⁺, CaYBO₄:Bi³⁺, CaYBO₄:Eu³⁺, CaYB_{0.8}O_{3.7}:Eu³⁺, CaY₂ZrO₆:Eu³⁺, (Ca,Zn,Mg)₃(PO₄)₂:Sn, CeF₃, (Ce,Mg)BaAl₁₁O₁₈:Ce, (Ce,Mg)SrAl₁₁O₁₈:Ce, CeMgAl₁₁O₁₉:Ce:Tb, Cd₂B₆O₁₁:Mn²⁺, CdS:Ag⁺,Cr, CdS:In, CdS:In, CdS:In,Te, CdS:Te, CdWO₄, CsF, CsI, CsI:Na⁺, CsI:Tl, (ErCl₃)_{0.25}(BaCl₂)_{0.75}, GaN:Zn, Gd₃Ga₅O₁₂:Cr³⁺, Gd₃Ga₅O₁₂:Cr,Ce, GdNbO₄:Bi³⁺, Gd₂O₂S:Eu³⁺, Gd₂O₂Pr³⁺, Gd₂O₂S:Pr,Ce,F, Gd₂O₂S:Tb³⁺, Gd₂SiO₅:Ce³⁺, KAl₁₁O₁₇:Tl⁺, KGa₁₁O₁₇:Mn²⁺, K₂La₂Ti₃O₁₀:Eu, KMgF₃:Eu²⁺, KMgF₃:Mn²⁺, K₂SiF₆:Mn⁴⁺, LaAl₃B₄O₁₂:Eu³⁺, LaAlB₂O₆:Eu³⁺, LaAlO₃:Eu³⁺, LaAlO₃:Sm³⁺, LaAsO₄:Eu³⁺, LaBr₃:Ce³⁺, LaBO₃:Eu³⁺, (La,Ce,Tb)PO₄:Ce:Tb, LaCl₃:Ce³⁺, La₂O₃:Bi³⁺, LaOBr:Tb³⁺, LaOBr:Tm³⁺, LaOCl:Bi³⁺, LaOCl:Eu³⁺, LaOF:Eu³⁺, La₂O₃:Eu³⁺, La₂O₃:Pr³⁺, La₂O₂S:Tb³⁺, LaPO₄:Ce³⁺, LaPO₄:Eu³⁺, LaSiO₃Cl:Ce³⁺, LaSiO₃Cl:Ce³⁺,Tb³⁺, LaVO₄:Eu³⁺, La₂W₃O₁₂:Eu³⁺, LiAlF₄:Mn²⁺, LiAl₅O₈:Fe³⁺, LiAlO₂:Fe³⁺, LiAlO₂:Mn²⁺, LiAl₅O₈:Mn²⁺, Li₂CaP₂O₇:Ce³⁺,Mn²⁺, LiCeBa₄Si₄O₁₄:Mn²⁺, LiCeSrBa₃Si₄O₁₄:Mn²⁺, LiInO₂:Eu³⁺, LiInO₂:Sm³⁺, LiLaO₂:Eu³⁺, LuAlO₃:Ce³⁺, (Lu,Gd)₂SiO₅:Ce³⁺, Lu₂SiO₅:Ce³⁺, Lu₂Si₂O₇:Ce³⁺, LuTaO₄:Nb⁵⁺, Lu₁₋ₓYₓAlO₃:Ce³⁺, MgAl₂O₄:Mn²⁺, MgSrAl₁₀O₁₇:Ce, MgB₂O₄:Mn²⁺, MgBa₂(PO₄)₂:Sn²⁺, MgBa₂(PO₄)₂:U, MgBaP₂O₇:Eu²⁺, MgBaP₂O₇:Eu²⁺,Mn²⁺, MgBa₃Si₂O₈:Eu²⁺, MgBa(SO₄)₂:Eu²⁺, Mg₃Ca₃(PO₄)₄:Eu²⁺, MgCaP₂O₇:Mn²⁺, Mg₂Ca(SO₄)₃:Eu²⁺, Mg₂Ca(SO₄)₃:Eu²⁺,Mn², MgCeAlₙO₁₉:Tb³⁺, Mg₄(F)GeO₆:Mn²⁺, Mg₄(F)(Ge,Sn)O₆:Mn²⁺, MgF₂:Mn²⁺, MgGa₂O₄:Mn²⁺, Mg₈Ge₂O₁₁F₂:Mn⁴⁺, MgS:Eu²⁺, MgSiO₃:Mn²⁺, Mg₂SiO₄:Mn²⁺, Mg₃SiO₃F₄:Ti⁴⁺, MgSO₄:Eu²⁺, MgSO₄:Pb²⁺, MgSrBa₂Si₂O₇:Eu²⁺, MgSrP₂O₇:Eu²⁺, MgSr₅(PO₄)₄:Sn²⁺, MgSr₃Si₂O₈:Eu²⁺,Mn²⁺, Mg₂Sr(SO₄)₃:Eu²⁺, Mg₂TiO₄:Mn⁴⁺, MgWO₄, MgYBO₄:Eu³⁺, Na₃Ce(PO₄)₂:Tb³⁺, NaI:Tl, Na_{1.23}K_{0.42}Eu_{0.12}TiSi₄O₁₁:Eu³⁺, Na_{1.23}K_{0.42}Eu_{0.12}TiSi₅O₁₃.xH₂O:Eu³⁺, Na_{1.29}K_{0.46}Er_{0.08}TiSi₄O₁₁:Eu³⁺, Na₂Mg₃Al₂Si₂O₁₀:Tb, Na(Mg₂₋ₓMnₓ)LiSi₄O₁₀F₂:Mn, NaYF₄:Er³⁺, Yb³⁺, NaYO₂:Eu³⁺, P46(70%)+P47(30%), SrAl₁₂O₁₉:Ce³⁺, Mn²⁺, SrAl₂O₄:Eu²⁺, SrAl₄O₇:Eu³⁺, SrAl₁₂O₁₉:Eu²⁺, SrAl₂S₄:Eu²⁺, Sr₂B₅O₉Cl:Eu²⁺, SrB₄O₇:Eu²⁺ (F,Cl,Br), SrB₄O₇:Pb²⁺, SrB₄O₇:Pb²⁺, Mn²⁺, SrB₈O₁₃:Sm²⁺, SrₓBa_{y}Cl_{z}Al₂O_{4-z/2}: Mn²⁺, Ce³⁺, SrBaSiO₄:Eu²⁺, Sr(Cl,Br,I)₂:Eu²⁺ in SiO₂, SrCl₂:Eu²⁺ in SiO₂, Sr₅Cl(PO₄)₃:Eu, Sr_{w}FₓB₄O_{6.5}:Eu²⁺, Sr_{w}FₓB_{y}O_{z}:Eu²⁺,Sm²⁺, SrF₂:Eu²⁺, SrGa₁₂O₁₉:Mn²⁺, SrGa₂S₄:Ce³⁺, SrGa₂S₄:Eu²⁺, SrGa₂S₄:Pb²⁺, SrIn₂O₄:Pr³⁺, Al³⁺, (Sr,Mg)₃(PO₄)₂:Sn, SrMgSi₂O₆:Eu²⁺, Sr₂MgSi₂O₇:Eu²⁺, Sr₃MgSi₂O₈:Eu²⁺, SrMoO₄:U, SrO.3B₂O₃:Eu²⁺,Cl, β-SrO.3B₂O₃:Pb²⁺, β-SrO.3B₂O₃:Pb²⁺,Mn²⁺, α-SrO.3B₂O₃:Sm²⁺, Sr₆P₅BO₂₀:Eu, Sr₅(PO₄)₃Cl:Eu²⁺, Sr₅(PO₄)₃Cl:Eu²⁺,Pr³⁺, Sr₅(PO₄)₃Cl:Mn²⁺, Sr₅(PO₄)₃Cl:Sb³⁺, Sr₂P₂O₇:Eu²⁺, β-Sr₃(PO₄)₂:Eu²⁺, Sr₅(PO₄)₃F:Mn²⁺, Sr₅(PO₄)₃F:Sb³⁺, Sr₅(PO₄)₃F:Sb³⁺,Mn²⁺, Sr₅(PO₄)₃F:Sn²⁺, Sr₂P₂O₇:Sn²⁺, β-Sr₃(PO₄)₂:Sn²⁺, β-Sr₃(PO₄)₂:Sn²⁺,Mn²⁺ (Al), SrS:Ce³⁺, SrS:Eu²⁺, SrS:Mn²⁺, SrS:Cu⁺,Na, SrSO₄:Bi, SrSO₄:Ce³⁺, SrSO₄:Eu²⁺, SrSO₄:Eu²⁺,Mn²⁺, Sr₅Si₄O₁₀Cl₆:Eu²⁺, Sr₂SiO₄:Eu²⁺, SrTiO₃:Pr³⁺, SrTiO₃Pr³⁺,Al³⁺, Sr₃WO₆:U, SrY₂O₃:Eu³⁺, ThO₂:Eu³⁺, ThO₂:Pr³⁺, ThO₂:Tb³⁺, YAl₃B₄O₁₂:Bi³⁺, YAl₃B₄O₁₂:Ce³⁺, YAl₃B₄O₁₂:Ce³⁺,Mn, YAl₃B₄O₁₂:Ce³⁺,Tb³⁺, YAl₃B₄O₁₂:Eu³⁺, YAl₃B₄O₁₂:Eu³⁺,Cr³⁺, YAl₃B₄O₁₂:Th⁴⁺,Ce³⁺,Mn²⁺, YAlO₃:Ce³⁺, Y₃Al₅O₁₂:Ce³⁺, Y₃Al₅O₁₂:Cr³⁺, YAlO₃:Eu³⁺, Y₃Al₅O₁₂:Eu^{3r}, Y₄Al₂O₉:Eu³⁺, Y₃Al₅O₁₂:Mn⁴⁺, YAlO₃:Sm³⁺, YAlO₃:Tb³⁺, Y₃Al₅O₁₂:Tb³⁺, YAsO₄:Eu³⁺, YBO₃:Ce³⁺, YBO₃:Eu³⁺, YF₃:Er³⁺,Yb³⁺, YF₃:Mn²⁺, YF₃:Mn²⁺,Th⁴⁺, YF₃:Tm³⁺,Yb³⁺, (Y,Gd)BO₃:Eu, (Y,Gd)BO₃:Tb, (Y,Gd)₂O₃:Eu³⁺, Y_{1.34}Gd_{0.60}O₃(Eu,Pr), Y₂O₃:Bi³⁺, YOBrEu³⁺, Y₂O₃:Ce, Y₂O₃:Er³⁺, Y₂O₃:Eu³⁺ (YOE), Y₂O₃:Ce³⁺,Tb³⁺, YOCl:Ce³⁺, YOCl:Eu³⁺, YOF:Eu³⁺, YOF:Tb³⁺, Y₂O₃:Ho³⁺, Y₂O₂S:Eu³⁺, Y₂O₂S:Pr³⁺, Y₂O₂S:Tb³⁺, Y₂O₃:Tb³⁺, YPO₄:Ce³⁺, YPO₄:Ce³⁺,Tb³⁺, YPO₄:Eu³⁺, YPO₄:Mn²⁺,Th⁴⁺, YPO₄:V⁵⁺, Y(P,V)O₄:Eu, Y₂SiO₅:Ce³⁺, YTaO₄, YTaO₄:Nb⁵⁺, YVO₄:Dy³⁺, YVO₄:Eu³⁺, ZnAl₂O₄:Mn²⁺, ZnB₂O₄:Mn²⁺, ZnBa₂S₃:Mn²⁺, (Zn,Be)₂SiO₄:Mn²⁺, Zn_{0.4}Cd_{0.6}S:Ag, Zn_{0.6}Cd_{0.4}S:Ag, (Zn,Cd)S:Ag,Cl, (Zn,Cd)S:Cu, ZnF₂:Mn²⁺, ZnGa₂O₄, ZnGa₂O₄:Mn²⁺, ZnGa₂S₄:Mn²⁺, Zn₂GeO₄:Mn²⁺, (Zn,Mg)F₂:Mn²⁺, ZnMg₂(PO₄)₂:Mn²⁺, (Zn,Mg)₃(PO₄)₂:Mn²⁺, ZnO:Al³⁺,Ga³⁺, ZnO:Bi³⁺, ZnO:Ga³⁺, ZnO:Ga, ZnO—CdO:Ga, ZnO:S, ZnO:Se, ZnO:Zn, ZnS:Ag⁺,Cl⁻, ZnS:Ag,Cu,Cl, ZnS:Ag,Ni, ZnS:Au,In, ZnS—CdS (25-75), ZnS—CdS (50-50), ZnS—CdS (75-25), ZnS—CdS:Ag,Br,Ni, ZnS—CdS:Ag⁺,Cl, ZnS—CdS:Cu,Br, ZnS—CdS:Cu,I, ZnS:Cl⁻, ZnS:Eu²⁺, ZnS:Cu, ZnS:Cu⁺,Al³⁺, ZnS:Cu⁺,Cl⁻, ZnS:Cu,Sn, ZnS:Eu²⁺, ZnS:Mn²⁺, ZnS:Mn,Cu, ZnS:Mn²⁺,Te²⁺, ZnS:P, ZnS:Pb²⁺, ZnS:Pb²⁺,Cl⁻, ZnS:Pb,Cu, Zn₃(PO₄)₂:Mn²⁺, Zn₂SiO₄:Mn²⁺, Zn₂SiO₄:Mn²⁺,As⁵⁺, Zn₂SiO₄:Mn,Sb₂O₂, Zn₂SiO₄:Mn²⁺,P, Zn₂SiO₄:Ti⁴⁺, ZnS:Sn²⁺, ZnS:Sn,Ag, ZnS:Sn²⁺,Li⁺, ZnS:Te,Mn, ZnS—ZnTe:Mn²⁺, ZnSe:Cu⁺,Cl or ZnWO₄.

Compounds according to the invention give rise to good LED qualities even when employed in small amounts. The LED quality is described here via conventional parameters, such as, for example, the colour rendering index, the correlated colour temperature, lumen equivalents or absolute lumens, or the colour point in CIE x and CIE y coordinates.

The colour rendering index or CRI is a dimensionless lighting quantity, familiar to the person skilled in the art, which compares the colour reproduction faithfulness of an artificial light source with that of sunlight or filament light sources (the latter two have a CRI of 100).

The CCT or correlated colour temperature is a lighting quantity, familiar to the person skilled in the art, with the unit kelvin. The higher the numerical value, the colder the white light from an artificial radiation source appears to the observer. The CCT follows the concept of the black body radiator, whose colour temperature describes the so-called Planck curve in the CIE diagram.

The lumen equivalent is a lighting quantity, familiar to the person skilled in the art, with the unit lm/W which describes the magnitude of the photometric luminous flux in lumens of a light source at a certain radiometric radiation power with the unit watt. The higher the lumen equivalent, the more efficient a light source.

The lumen is a photometric lighting quantity, familiar to the person skilled in the art, which describes the luminous flux of a light source, which is a measure of the total visible radiation emitted by a radiation source. The greater the luminous flux, the brighter the light source appears to the observer.

CIE x and CIE y stand for the coordinates in the standard CIE colour diagram (here standard observer 1931), familiar to the person skilled in the art, by means of which the colour of a light source is described.

All the quantities mentioned above are calculated from emission spectra of the light source by methods familiar to the person skilled in the art.

In this connection, the present invention furthermore relates to the use of the compounds according to the invention or of the emission-converting material according to the invention described above in a light source.

The light source is particularly preferably an LED, in particular a phosphor-converted LED, pc-LED for short. It is particularly preferred here for the emission-converting material to comprise at least one further conversion phosphor besides the conversion phosphor according to the invention, in particular so that the light source emits white light or light having a certain colour point (colour-on-demand principle). “Colour-on-demand principle” is taken to mean the achievement of light having a certain colour point with a pc-LED using one or more conversion phosphors.

The present invention thus furthermore relates to a light source which comprises a primary light source and the emission-converting material.

Here too, it is particularly preferred for the emission-converting material to comprise at least one further conversion phosphor besides the conversion phosphor according to the invention, so that the light source preferably emits white light or light having a certain colour point.

The light source according to the invention is preferably a pc-LED. A pc-LED generally comprises a primary light source and an emission-converting material. The emission-converting material according to the invention can for this purpose either be dispersed in a resin (for example epoxy or silicone resin) or, given suitable size ratios, arranged directly on the primary light source or alternatively, depending on the application, remote therefrom (the latter arrangement also includes “remote phosphor technology”).

The primary light source can be a semiconductor chip, a luminescent light source, such as ZnO, a so-called TCO (transparent conducting oxide), a ZnSe- or SiC-based arrangement, an arrangement based on an organic light-emitting layer (OLED) or a plasma or discharge source, most preferably a semiconductor chip. If the primary light source is a semiconductor chip, it is preferably a luminescent indium aluminium gallium nitride (InAlGaN), as is known from the prior art. Possible forms of primary light sources of this type are known to the person skilled in the art. Furthermore, lasers are suitable as light source.

For use in light sources, in particular pc-LEDs, the emission-converting material according to the invention can also be converted into any desired outer shapes, such as spherical particles, flakes and structured materials and ceramics. These shapes are summarised under the term “shaped bodies”. The shaped bodies are consequently emission-converting shaped bodies.

The invention furthermore relates to a lighting unit which contains at least one light source according to the invention. Lighting units of this type are employed principally in display devices, in particular liquid-crystal display devices (LC displays) having backlighting. The present invention therefore also relates to a display device of this type.

In the lighting unit according to the invention, the optical coupling between the emission-converting material and the primary light source (in particular semiconductor chips) preferably takes place by means of a light-conducting arrangement. In this way, it is possible for the primary light source to be installed at a central location and for this to be optically coupled to the emission-converting material by means of light-conducting devices, such as, for example, optical fibres. In this way, it is possible to achieve lamps adapted to the lighting wishes which consist of one or more different conversion phosphors, which may be arranged to form a light screen, and an optical waveguide, which is coupled to the primary light source. In this way, it is possible to place a strong primary light source at a location which is favourable for electrical installation and to install lamps comprising emission-converting materials, which are coupled to the optical waveguides, without further electrical cabling, merely by laying optical waveguides at any desired locations.

All variants of the invention described here can be combined with one another so long as the respective embodiments are not mutually exclusive. In particular, it is an obvious operation, on the basis of the teaching of this specification, as part of routine optimisation, precisely to combine various variants described here in order to obtain a specific particularly preferred embodiment. The following examples are intended to illustrate the present invention and show, in particular, the result of such illustrative combinations of the invention variants described. However, they should in no way be regarded as limiting, but instead are intended to stimulate generalisation. All compounds or components which can be used in the preparations are either known and commercially available or can be synthesised by known methods. The temperatures indicated in the examples are always in ° C. It furthermore goes without saying that, both in the description and also in the examples, the amounts of the components added in the compositions always add up to a total of 100%. Percent data should always be regarded in the given connection.

### EXAMPLES

a) Tb_{1.998}Eu_{0.002}Mo₃O₁₂

1.8684 g (2.498 mmol) of Tb₄O₇, 2.1591 g (15.00 mmol) of MoO₃ and 0.0018 g (0.0050 mmol) of Eu₂O₃ are triturated in an agate mortar with the aid of acetone. The powder is dried, transferred into a porcelain crucible and heated twice in air at 900° C. for 10 h.

b) Tb_{1.8}Eu_{0.2}Mo₃O₁₂

1.6832 g (2.250 mmol) of Tb₄O₇, 2.1591 g (15.00 mmol) of MoO₃ and 0.1760 g (0.5000 mmol) of Eu₂O₃ are triturated in an agate mortar with the aid of acetone. The powder is dried, transferred into a porcelain crucible and heated twice in air at 900° C. for 10 h.

c) TbEuMo₃O₁₂

0.9351 g (1.250 mmol) of Tb₄O₇, 2.1591 g (15.00 mmol) of MoO₃ and 0.8800 g (2.500 mmol) of Eu₂O₃ are triturated in an agate mortar with the aid of acetone. The powder is dried, transferred into a porcelain crucible and heated twice in air at 900° C. for 10 h.

d) Tb_{1.8}Sm_{0.2}Mo₃O₁₂

1.6823 g (2.250 mmol) of Tb₄O₇, 2.1591 g (15.00 mmol) of MoO₃ and 0.1744 g (0.500 mmol) of Sm₂O₃ are triturated in an agate mortar with the aid of acetone. The powder is dried, transferred into a porcelain crucible and heated twice in air at 900° C. for 10 h.

e) Tb_{1.2}Eu_{0.8}Mo₃O₁₂

1.1215 g (1.500 mmol) of Tb₄O₇, 2.1591 g (15.00 mmol) of MoO₃ and 0.7038 g (2.000 mmol) of Sm₂O₃ are triturated in an agate mortar with the aid of acetone. The powder is dried, transferred into a porcelain crucible and heated twice in air at 900° C. for 10 h.

f) Production of a Pc-LED Using a Phosphor of the Composition Tb_{1.2}Eu_{0.8}Mo₃O₁₂ Prepared in Accordance with the Invention:

2 g of the phosphor having the composition Tb_{1.2}Eu_{0.8}Mo₃O₁₂ are weighed out, mixed with 8 g of an optically transparent silicone and subsequently mixed homogeneously in a planetary centrifugal mixer so that the phosphor concentration in the overall mass is 20% by weight. The silicone/phosphor mixture obtained in this way is applied to the chip of a near-UV semiconductor LED with the aid of an automatic dispenser and cured with supply of heat. The near-UV semiconductor LEDs used for the LED characterisation in the present example have an emission wavelength of 395 nm and are operated at a current strength of 350 mA. The photometric characterisation of the LED is carried out using an Instrument Systems CAS 140 spectrometer and an attached ISP 250 integration sphere. The LED is characterised via determination of the wavelength-dependent spectral power density. The resultant spectrum of the light emitted by the LED is used to calculate the colour point coordinates CIE x and y.

### DESCRIPTION OF THE FIGURES

FIG. 1. X-ray diffraction patterns of Tb₂₋ₓLnₓMo₃O₁₂ for Cu K-alpha radiation

FIG. 2. Reflection spectra of Tb_{1.999}Eu_{0.001}Mo₃O₁₂ against BaSO₄ as white standard

FIG. 3. Reflection spectra of Tb_{1.8}Eu_{0.2}Mo₃O₁₂ against BaSO₄ as white standard

FIG. 4. Reflection spectra of TbEuMo₃O₁₂ against BaSO₄ as white standard

FIG. 5. Reflection spectrum of Tb_{1.8}Sm_{0.2}Mo₃O₁₂ against BaSO₄ as white standard

FIG. 6. Excitation spectra of Tb_{1.999}Eu_{0.001}Mo₃O₁₂ (λₑₘ=615 nm)

FIG. 7. Excitation spectra of Tb_{1.8}EU_{0.2}Mo₃O₁₂ (λₑₘ=615 nm)

FIG. 8. Excitation spectra of TbEuMo₃O₁₂ (λₑₘ=615 nm)

FIG. 9. Excitation spectrum of Tb_{1.8}Sm_{0.2}Mo₃O₁₂ (λₑₘ=600 nm)

FIG. 10. Emission spectra of Tb_{1.999}Eu_{0.001}Mo₃O₁₂ (λₑₓ=487.0 nm)

FIG. 11. Emission spectra of Tb_{1.8}EU_{0.2}Mo₃O₁₂ (λₑₓ=487.0 nm)

FIG. 12. Emission spectrum of TbEuMo₃O₁₂ (λₑₓ=487.0 nm)

FIG. 13. Emission spectrum of Tb_{1.8}Sm_{0.2}Mo₃O₁₂ (λₑₓ=487.0 nm)

FIG. 14. Section from the CIE 1931 colour diagram with the colour points of Tb₂₋ₓEuₓMo₃O₁₂

FIG. 15. Lattice constants of the mixed-crystal series of orthorhombic Tb₂,EuₓMo₃O₁₂

FIG. 16. LED spectrum of the pc-LED described in Example f)

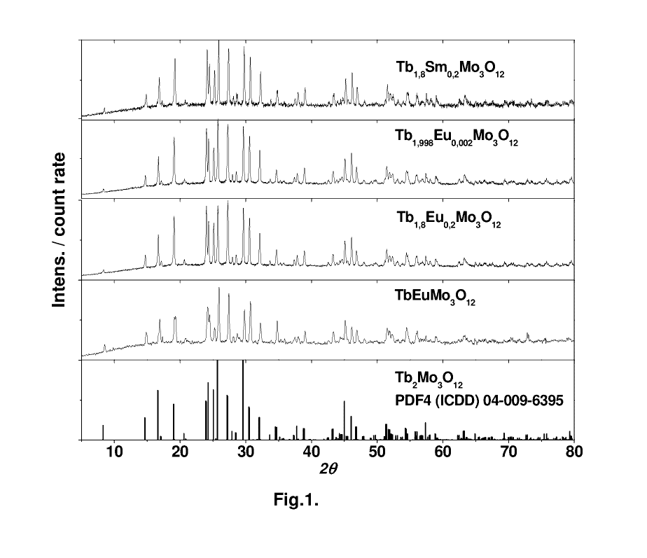

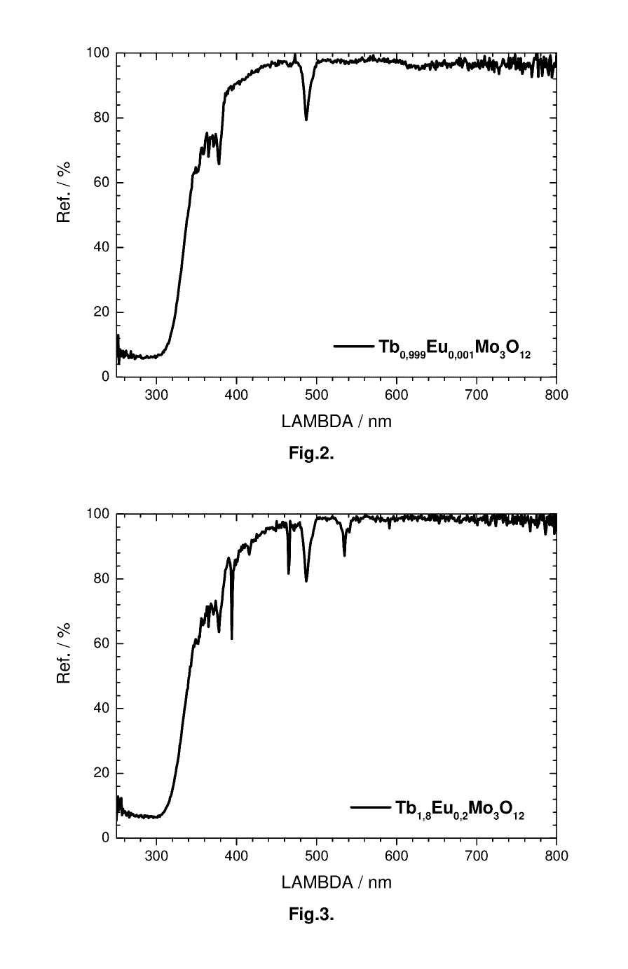

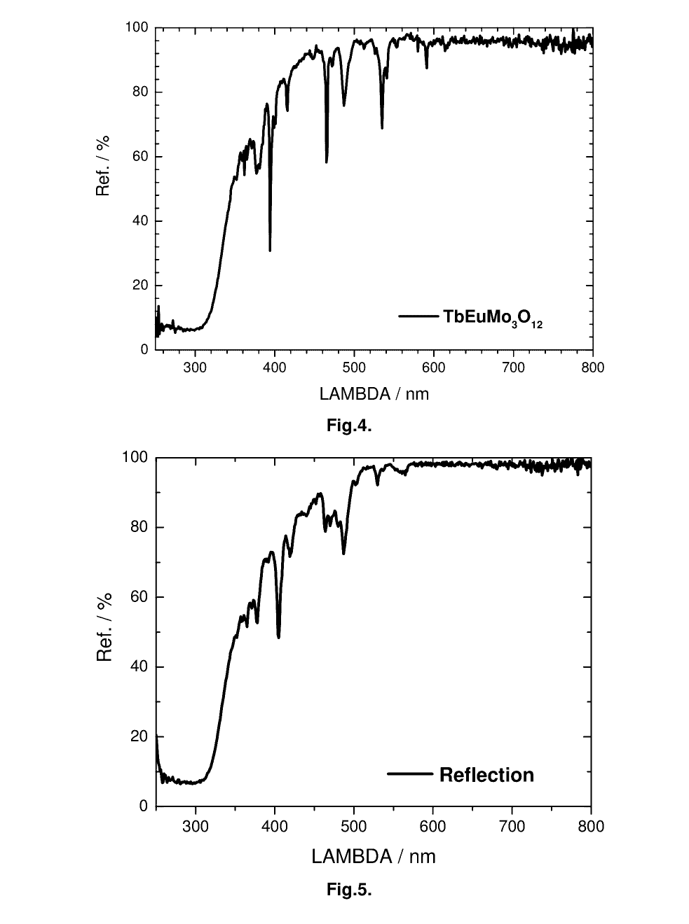

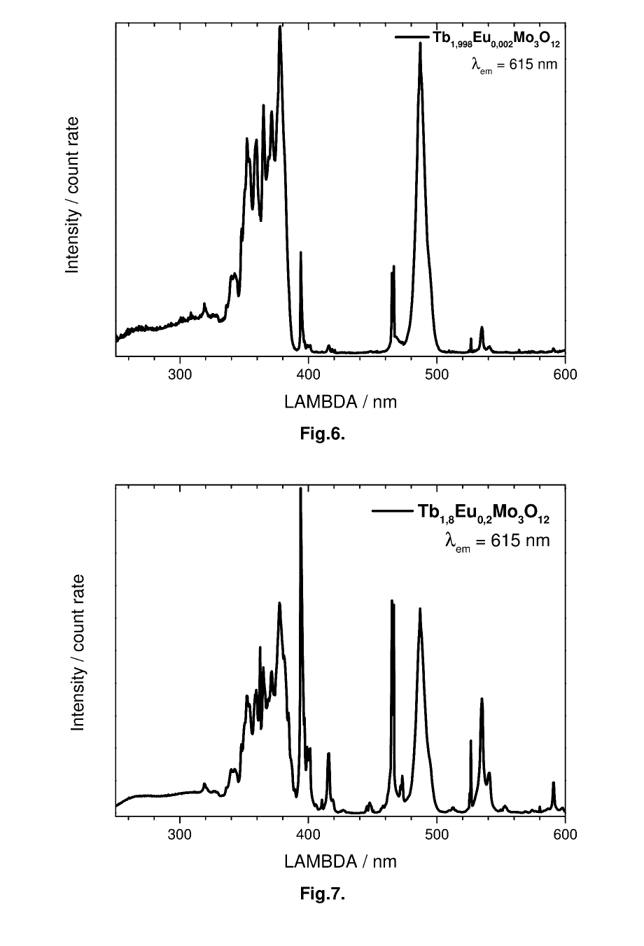

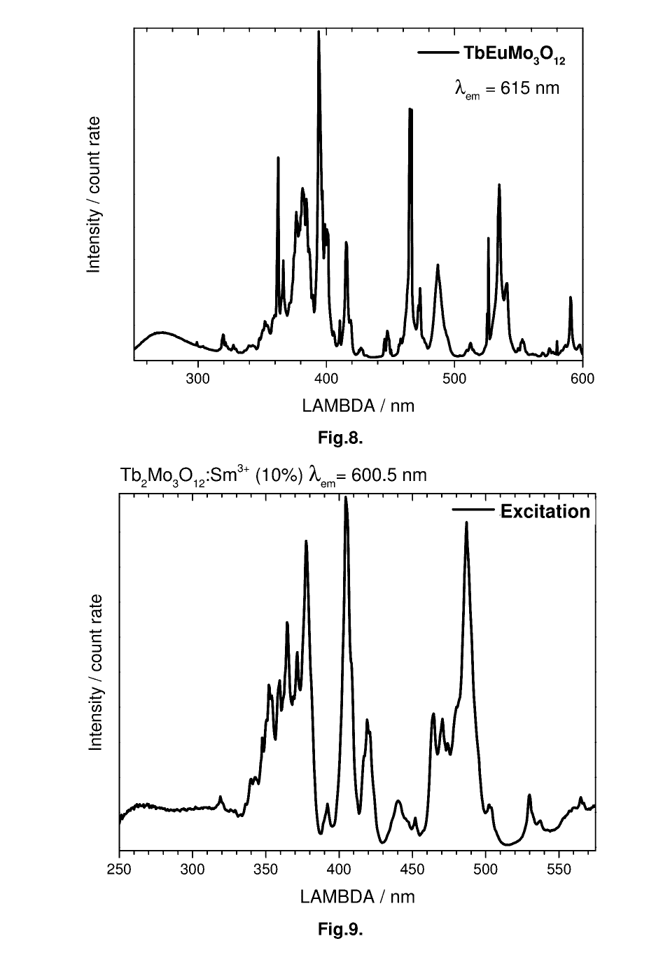

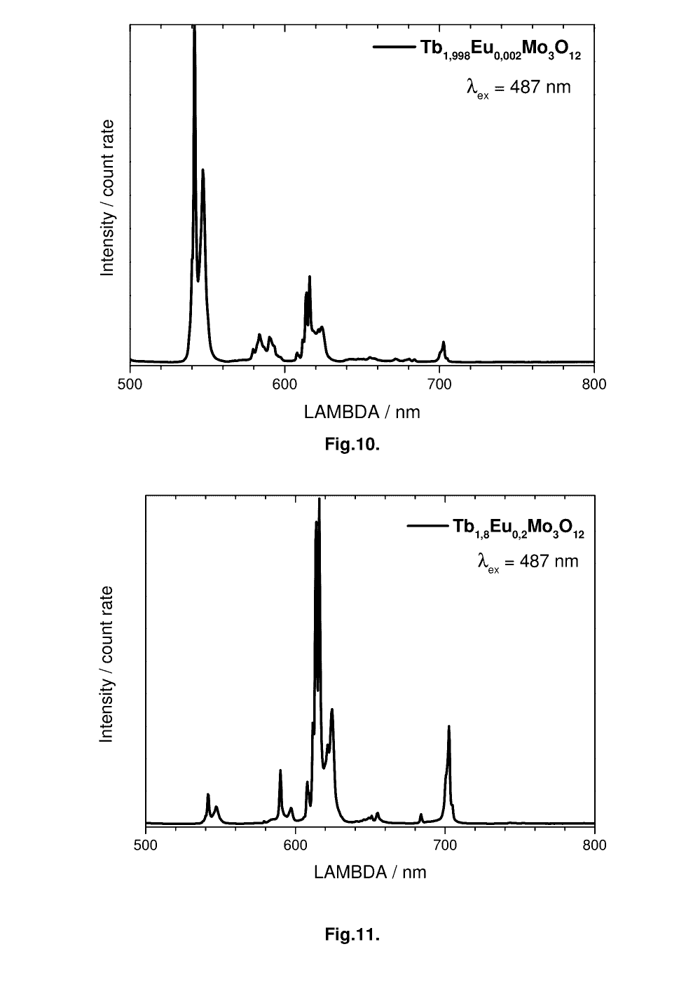

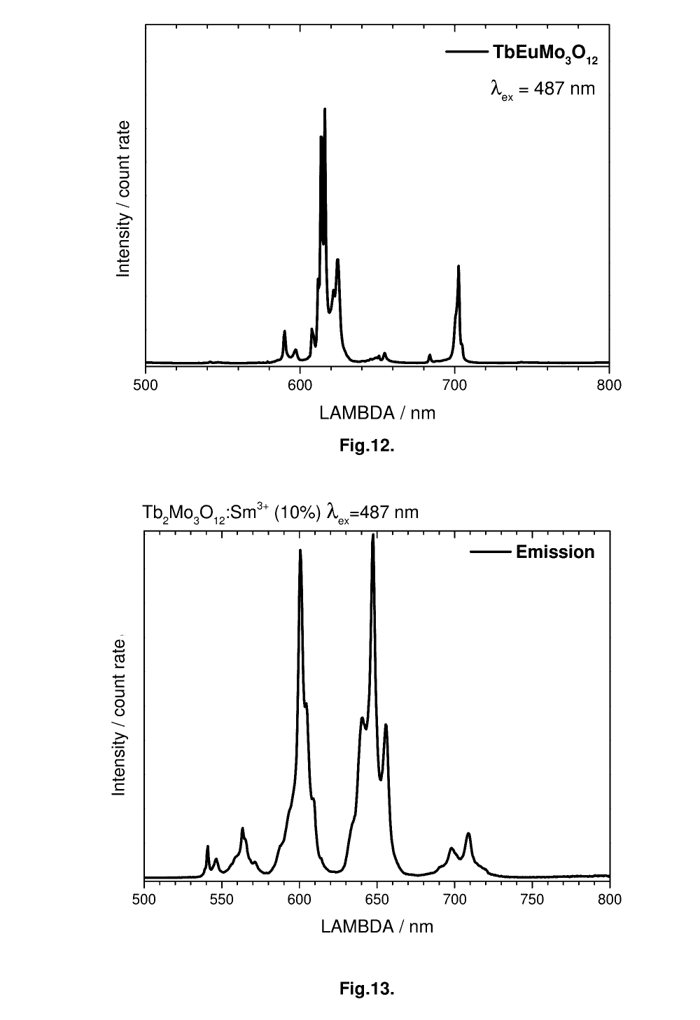

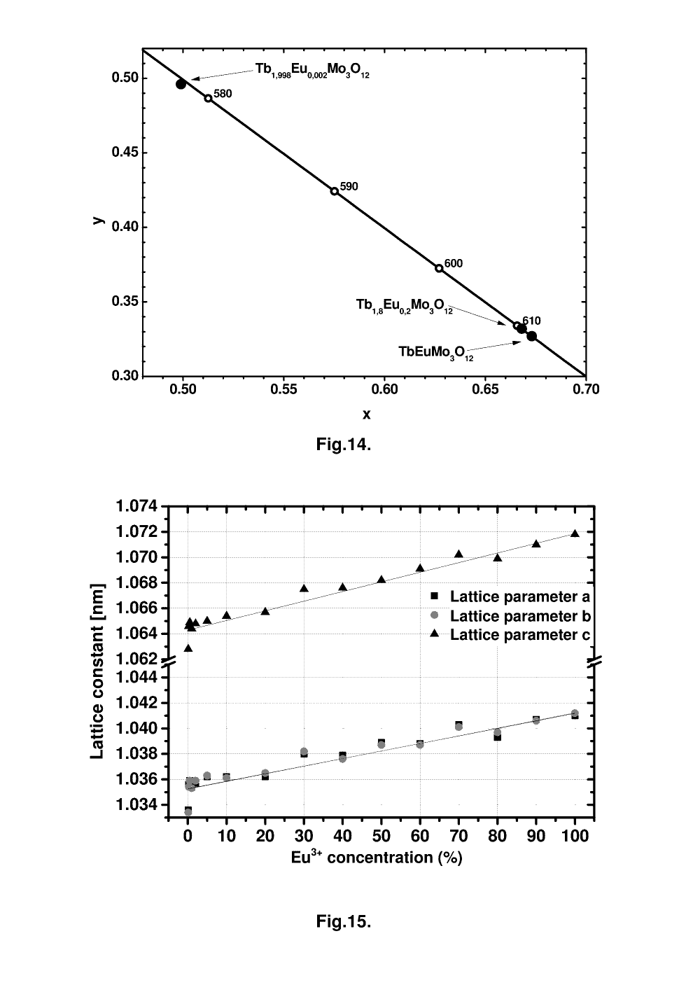

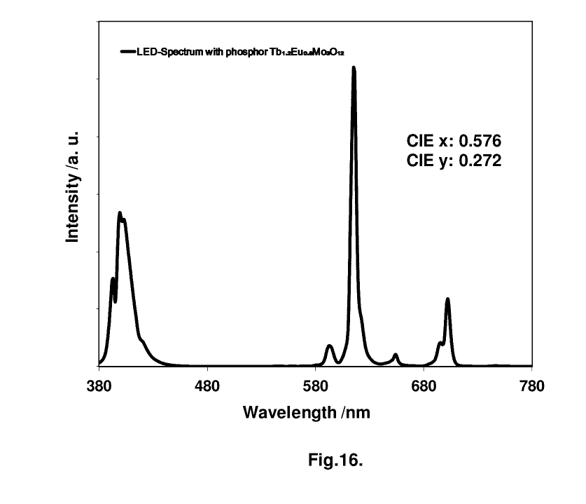

1. Compound of the formula I,
(Tb₂)ₓ(Mo_{1-b}W_{b})_{y}O_{3x+3y}:Ln I
in which
Ln denotes Sm³⁺ or Eu³⁺;
x denotes 1, 2 or 3;
1≦y≦8; and
0≦b<1.

2. Compound according to claim 1 selected from the formula Ia
(Tb₂₋ₐLnₐ)ₓ(Mo_{1-b}W_{b})_{y}O_{3x+3y} Ia
in which Ln, x, y and b have one of the meanings indicated in claim 1, and 0.1≦a≦1.

3. A compound according to claim 1, characterised in that they are in phase-pure form.

4. A compound according to claim 1, in which 0.2≦a≦1.

5. A compound according to claim 1, in which 0.4≦a≦1.

6. A compound according to claim 1, in which Ln is equal to Sm³⁺.

7. A compound according to claim 1, in which x is equal to 1.

8. A compound according to claim 1, in which y is equal to 3.

9. A compound according to claim 1, in which b is equal to 0.

10. A process for the preparation of a compound according to claim 1, characterised in that, in a step a), suitable starting materials selected from nitrides, and oxides or corresponding reactive forms of a europium or samarium source, a molybdenum source and a terbium source, and optionally a tungsten source, are mixed, and, in a step b), the mixture is thermally treated.

11. A method which comprises partially or completely converting a blue or near-UV emission into visible light of a longer wavelength, which comprises converting the blue or near-UV emission using a compound according to claim 1.

12. An emission-converting material comprising a compound according to claim 1 and one or more further conversion phosphors.

13. A light source having at least one primary light source, characterised in that the light source comprises at least one compound according to claim 1 and one or more further conversion phosphors.

14. A lighting unit, in particular for the backlighting of display devices, characterised in that it contains at least one light source according to claim 13.

15. A display device, in particular liquid-crystal display device (LC display), having backlighting, characterised in that it contains at least one lighting unit according to claim 14.
